(19) United States
(12) Patent Application Publication
(10) Pub. No.: US 2026/0344402 A1
(43) Pub. Date: Oct. 29, 2026

(54) POSITIONING OF GATE BUS THROUGH INTERMEDIATE POINT OF FINGERS IN FINGER LATERAL FIELD EFFECT TRANSISTOR

(71) Applicant: Infineon Technologies Austria AG, Villach (AT)

(72) Inventors: Ahmad MIZANNOJEHDEHI, Stittsville (CA); Iman ABDALI MASHHADI, Ottawa (CA); Thomas MACELWEE, Nepean (CA); Hongrui LU, Ottawa (CA)

(21) Appl. No.: 19/187,655

(22) Filed: Apr. 23, 2025

(51) Int. Cl. H10W 20/41; H10D 30/47; H10D 62/85; H10W 20/00

(52) U.S. Cl. CPC H10W 20/427; H10W 20/067; H10D 30/471; H10D 62/8503

(57) ABSTRACT

A lateral finger field effect transistor that has a gate bus that extends through an intermediate position of the fingers, and where the source fingers also extend from a source bus positioned also at the intermediate position. This reduces the length of the gate finger terminals and the source finger terminals, and thus reduces the voltage drop along the gate and source finger terminals. Thus, when the transistor is on, the gate-to-source voltage is better preserved along the entire length of the fingers. Accordingly, the lateral finger field effect transistors is more properly biased along the full length of the fingers of the field effect transistor. Furthermore, common source inductance is at least partially cancelled since the direction of current flow in the gate and source terminals is still in the opposite direction.

### BACKGROUND

Electronic circuits typically include transistors, which are devices that function as electronic switches that regulate or control current flow in portions of the circuit. A lateral field effect transistor (FET) is a type of transistor where a semiconductor channel region is disposed laterally between a drain terminal and the source terminal. “Laterally” means in the plane of the epitaxial stack which is perpendicular to the direction of epitaxial growth that formed the epitaxial stack. The lateral transistor includes a source active region that is connected to a source terminal, and a drain active region that is connected to a drain terminal.

When the lateral transistor is on, current flows laterally through the semiconductor channel region from the source active region to the drain active region. When the transistor is off, lesser or no current flows through the semiconductor channel region between the source active region and the drain active. The gate terminal is disposed over the semiconductor channel region between the source terminal and the drain terminal in such proximity that signals applied to the gate terminal affect whether the semiconductor channel region conducts current from the source active region to the drain active region.

The subject matter claimed herein is not limited to embodiments that solve any disadvantages or that operate only in environments such as those described above. Rather, this background is only provided to illustrate one exemplary technology area where some embodiments described herein may be practiced.

### BRIEF SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Embodiments described herein relate to a lateral finger field effect transistor that has a gate bus that extends through an intermediate position of the fingers, and where the source fingers also extend from a source bus positioned also at the intermediate position. This reduces the length of the gate finger terminals and the source finger terminals, and thus reduces the voltage drop along the gate and source finger terminals. Thus, when the transistor is on, the gate-to-source voltage is better preserved along the entire length of the fingers. Accordingly, the lateral finger field effect transistors is more properly biased along the full length of the fingers of the field effect transistor. Furthermore, common source inductance is at least partially cancelled since the direction of current flow in the gate and source terminals is still in the opposite direction.

Additional features and advantages will be set forth in the description which follows, and in part will be obvious from the description, or may be learned by the practice of the teachings herein. Features and advantages of the invention may be realized and obtained by means of the instruments and combinations particularly pointed out in the appended claims. Features of the present invention will become more fully apparent from the following description and appended claims or may be learned by the practice of the invention as set forth hereinafter.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings in which:

FIG. 1 illustrates a layer stack view (a top view) of a finger lateral field effect transistor that represents one very specific example of an embodiment of the broader principles described herein;

FIG. 2 illustrates an example of a side view of the metal stack that is illustrated in FIG. 1;

FIG. 3 illustrates a flowchart of a method for fabricating the transistor of FIG. 1;

FIGS. 4A through 4F illustrate successive fabrication states of the transistor of FIG. 1; and

FIG. 5 illustrates a top view of an example alternative transistor that has multiple gate busses at intermediate positions along the fingers of a lateral field effect transistor.

### DETAILED DESCRIPTION

Embodiments described herein relate to a lateral finger field effect transistor that has a gate bus that extends through an intermediate position of the fingers, and where the source fingers also extend from a source bus positioned also at the intermediate position. This reduces the length of the gate finger terminals and the source finger terminals, and thus reduces the voltage drop along the gate and source finger terminals. Thus, when the transistor is on, the gate-to-source voltage is better preserved along the entire length of the fingers. Accordingly, the lateral finger field effect transistors is more properly biased along the full length of the fingers of the field effect transistor. Furthermore, common source inductance is at least partially cancelled since the direction of current flow in the gate and source terminals is still in the opposite direction.

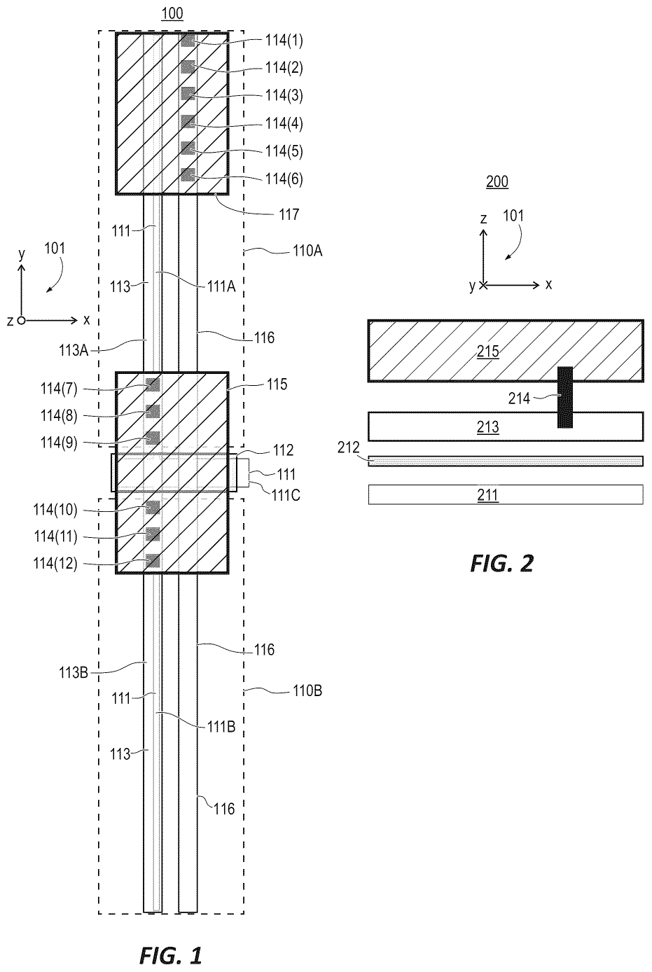

FIG. 1 illustrates a layer stack view (a top view) of a finger lateral field effect transistor 100 that represents one very specific example of an embodiment of the broader principles described herein. The three-dimensional (3D) Cartesian axes 101 are also illustrated and will be used as a convention for clarity in describing particular directions. The axes 101 are used throughout the figures and in the description as a convention. For example, the lateral field effect transistor 100 is formed via epitaxial growth of various layers one on top of the other. The direction of this epitaxial growth is in the positive z direction referring to the axes 101 (which would be the direction coming out of the page towards the reader). On the other hand, each layer in that epitaxial stack is layered in a plane defined by the x-axis and the y-axis (also referred to herein as the “xy plane” or a “lateral plane”). For clarity, this would be in the plane of the drawing itself. Thus, FIG. 1 is a top view looking down against the direction of epitaxial growth. Terms that describe vertical relationships, movement, or directions (e.g., upwards, downwards, underlying, overlying, below, above, and so forth) are with respect to the z direction, unless otherwise stated.

Furthermore, for clarity, in the layer stack view of FIG. 1, relevant metal layers of the epitaxial stack are all visible even though, in an actual transistor, the metal layers are opaque and thus would block a view of the underlying layers in an actual structure. However, in FIG. 1, a stack of metal layers is illustrated in which when a structure underlies another structure, the underlying structure is still shown but in lighter form. This is for clarity to allow a proper visual understanding of the relationship between overlying and underlying metal layers. Other non-conductive structures are not shown so that emphasis can be focused on the metal layers and their relationship with each other and the underlying active regions.

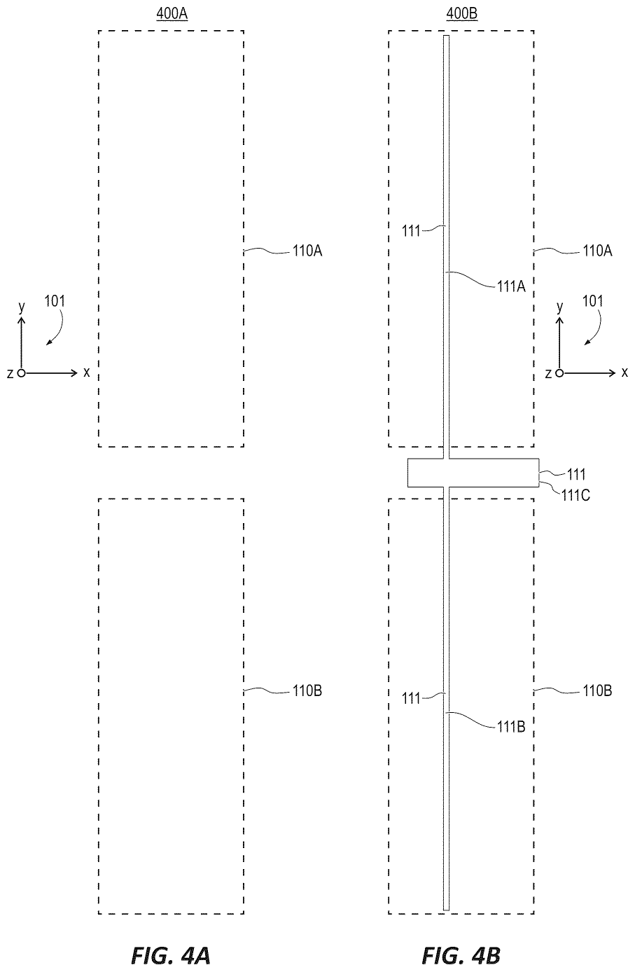

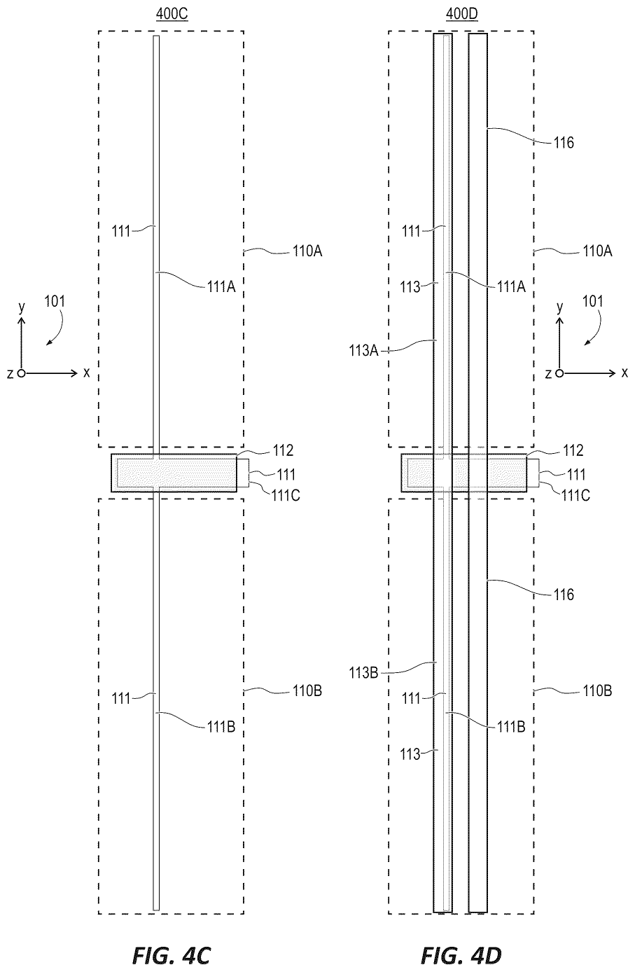

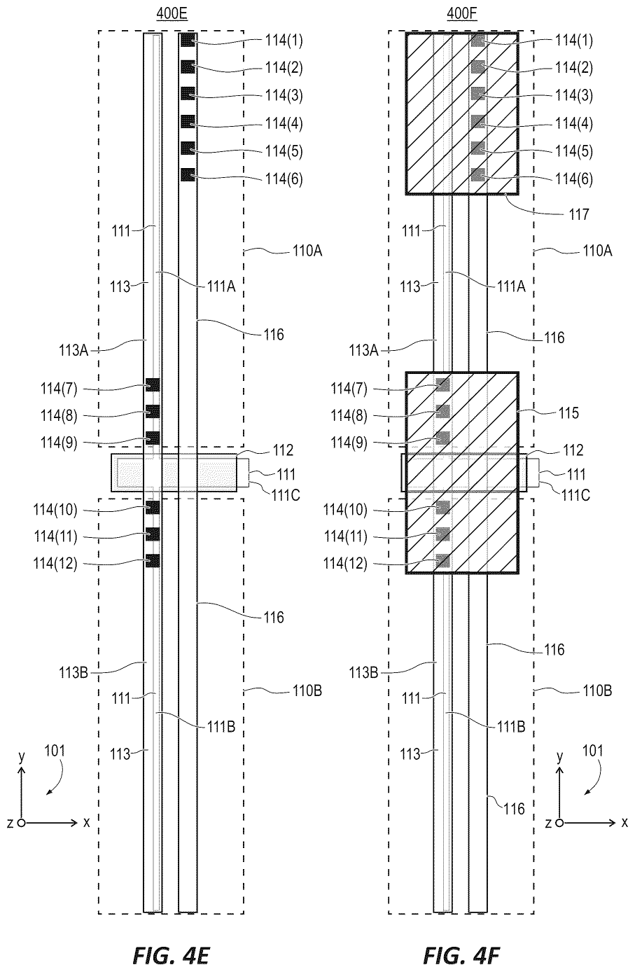

The metal layers are formed over and in the context of underlying active regions 110A and 110B. These active regions 110A and 110B are formed of semiconductor material. In FIG. 1, the active regions 110A and 110B are shown as boxes with dashed-lined borders, and no fill except where altered by overlying layers. For further clarity, FIG. 4A illustrates a fabrication state 400A of the transistor 100 showing only the active regions 110A and 110B. In the convention used herein, elements that are more operational with the active region 110A will be labelled with the suffix “A”; and elements that are more operational with the active region 110B will be labelled with the suffix “B”. Elements that are operational to both active regions will not have an alphabetic suffix or will be labelled with the suffix “C”.

FIG. 2 illustrates an example of a side view of the metal stack 200 that is illustrated in FIG. 1. The lowest metal layer is a gate metal layer 211, which is used to form a gate terminal 111. The gate terminal 111 is illustrated as being bounded by an outline with solid lines, except where altered by overlying layers. For further clarity, FIG. 4B illustrates a fabrication state 400B of the transistor 100 showing the gate terminal 111 formed over the active regions 110A and 110B. The gate terminal 111 includes a gate bus 111C and a finger gate terminal that includes finger gate terminal portions 111A and 111B. The gate terminal 111 is integrated such that finger gate terminal portions 111A and 111B are both electrically connected to the gate bus 111C, being within the same gate metal layer 211.

The finger gate terminal portion 111A is elongated from the gate bus 111C in the positive y-direction (in a lateral plane of the metal layer 211) and extends over the active region 110A. On the other hand, the finger gate terminal portion 111B is elongated from the gate bus 111C in the negative y-direction (in a lateral plane of the metal layer 211) and extends over the active region 110B. The finger gate terminal portions 111A and 111B are collinear, occupying the same x and z coordinates in FIG. 1, and extending along the y-axis. The finger gate terminal portions 111A and 111B are in such vertical proximity to their respective active regions 110A and 110B that signals applied to the gate terminal 111 apply appropriate electrical field effects into the active regions 110A and 110B so as to effectively control whether the underlying active region is conductive (to turn the transistor 100 on) or non-conductive (to turn the transistor 100 off).

The point at which the finger gate terminal portion 111A and the gate bus 111C are connected will be referred to as “a proximate end” of the finger gate terminal portion 111A, and the point of the finger gate terminal portion111A that is most distant from the gate bus 111C will be referred to as the “distal end” of the finger gate terminal portion 111A. Similarly, the point at which the finger gate terminal portion 111B and the gate bus 111C are connected will be referred to as “a proximate end” of the finger gate terminal portion 111B, and the point of the finger gate terminal portion 111B that is most distant from the gate bus 111C will be referred to as the “distal end” of the finger gate terminal portion 111B.

Moving upwards in the positive z direction, but skipping a shield metal layer 212 for now, there is a source and drain metal layer 213 used to form a finger drain terminal 116 and a finger source terminal 113 that comprises finger source portions 113A and 113B. For further clarity, ignoring the presence of the shield metal 112 for now, FIG. 4D illustrates a fabrication state 400D of the transistor 100 showing the formation of the finger source terminal 113 and the finger drain terminal over the gate terminal 111.

The finger source portion 113A extends from the proximity of the gate bus 111C in the positive y-direction (in a lateral plane of the metal layer 213) over the active region 110A. On the other hand, the finger source portion 113B extends from the proximity of the gate bus 111C in the negative y-direction (in a lateral plane of the metal layer 213) over the active region 110B. The finger source portions 113A and 113B are collinear, occupying the same x and z coordinates in FIG. 1, and extending along the y-axis. Furthermore, although not required, the finger source portions 113A and 113B are contiguous defining one finger source terminal 113.

Thus, the finger source terminal 113 extends parallel to the finger gate terminal portions 111A and 111B. Specifically, the finger source portion 113A extends over the active region 110A parallel to and along the finger gate terminal portion 111A; and the finger source portion 113B extends over the active region 110B parallel to and along the finger gate terminal portion 111B. The finger source terminal 113 is not electrically connected to the gate terminal 111, but makes contact with an underlying source (not shown) that is elongated in the y-direction and that makes contact with the semiconductor of the respective active regions 110A and 110B.

The source and drain metal layer 213 also includes a finger drain terminal 116, which is also elongated along the y-axis (in a lateral plane of the metal layer 213) over substantially the entire y-axis extent of the active regions 110A and 110B. The finger drain terminal 116 makes contact with an underlying drain (not shown) that is elongated in the y-direction and that makes contact with the semiconductor of the respective active regions 110A and 110B.

Thus, the finger gate terminal (constituting finger gate terminal portions 111A and 111B), the finger source terminal 113 and the finger drain terminal 116 are substantially parallel. When an appropriate signal is applied to the gate terminal, and when there is a high positive voltage on the drain as compared to any voltage on the source, substantial current flows in the negative x-direction from the drain to the source. The current is substantial because this occurs along the entire extent (in the y-direction) of the active regions 110A allowing a wide current flow path. Furthermore, the transistor 100 may in fact have numerous such fingers allowing for substantial current to flow across the transistor.

The transistor 100 may be, as an example only, a High Electron Mobility Transistor (HEMT). In this case, the gate terminal may be in much closer proximity in the x-direction to the finger source terminal 113 (and the underlying source that contacts the active regions) than the finger drain terminal 116 (and the underlying drain that contacts the active region). Furthermore, the finger source terminal 113 may also be connected to field plates (not shown) that serve to control the electric field profile in the active regions. As a more specific example, the transistor 100 may be a Gallium Nitride (GaN) HEMT. However, the principles described herein are not limited to such a transistor, as the benefits of reduced debiasing effect and common source inductance may be achieved for any lateral field-effect transistor due to the intermediate placement of the gate bus reducing the finger length of the gate finger portions and the source finger portions.

Returning to the shield metal layer 212 of FIG. 2, the shield metal layer 212 is formed between the gate metal layer 211 and the source and drain metal layer 213. The shield metal layer 212 is illustrated as shield metal 112 in FIG. 2 and has light gray fill. As an example, the shield metal layer 212 may be composed of titanium nitride (TiN). The shield metal 112 is vertically disposed between the gate bus 111C and the intersecting portion of the finger drain terminal 116. For clarity, FIG. 4C illustrates a fabrication state 400C in which the shield metal 112 is formed over (but not electrically contacted with) the underlying gate bus 111C. This occurs before the formation of the finger source terminals and the finger gate terminals in FIG. 4D. The shield metal 112 prevents the high voltages present on the finger drain terminal 116 from electromagnetically interfering with the voltage applied to the gate bus 111C. Such shielding is particularly helpful when the voltages applied to the finger drain terminal 116 are high, such as in the hundreds of volts or higher, and/or subject to rapid and large voltage changes.

Moving upwards in FIG. 2, there is a via layer 214 in which vias are formed. For instance, in FIG. 1, there are twelve vias 114(1) through 114(12) illustrated. The via 214 and the vias 114(1) through 114(12) are illustrated as small solid-filled boxes. FIG. 4E illustrates a fabrication state 400E in which the vias 114(1) through 114(6) are formed over and in contact with the drain terminal 116, in which the vias 114(7) through 114(9) are formed over and in contact with finger source portion 113A, and in which 114(10) through 114(12) are formed over and in contact with finger source portion 113B.

Moving upwards in FIG. 2, we arrive at the bus metal layer 215. The bus metal layer 215 is used to form a drain bus 117 and a source bus 115. The bus metal layer 215, the drain bus 117 and the source bus 115 are each illustrated as being a box filled with rightward leaning hash-marking. The drain bus 117 is connected to the finger drain terminal 116 with vias 114(1) through 114(6). The source bus 115 overlies the gate bus 111C. The source bus 115 is connected to the finger source portion 113A of the finger source terminal using the vias 114(7) through 114(9), and to the finger source portion 113B using the vias 114(10) through 114(12). Thus, a source voltage (which may be ground) is applied to the source bus 115, a drain voltage (which may be very high in the hundreds or thousands of volts) is applied to the drain bus 117, and a control signal is applied to the gate bus 111C to thereby turn the transistor 100 on and off. The point at which the finger source portion 113A connects to the source bus 115 will be referred to as “a proximate end” of the finger source portion 113A. The point at which the finger source portion 113B connects to the source bus 115 will be referred to as “a proximate end” of the finger source portion 113B.

In FIG. 1, the gate bus 111C is in the middle of the y-axis extent of the active regions of the transistor 100. Compared to having the gate bus at one y-axis end of the active regions, this reduces the length that current flows to get to each end of the gate finger terminals. Thus, voltage drops are reduced in the gate finger terminal portions 111A and 111B, allowing for more of the voltage to reach even the distal ends of the gate finger terminal portions. Furthermore, compared to having the source bus at one y-axis end of the axis regions, the length of the source finger portions 113A and 113B are reduced, allowing for the applied at the source bus to with greater fidelity reach the distal ends of the source finger portions. Accordingly, the lateral finger field effect transistor is more properly biased along the full length of the fingers of the field effect transistor, reducing the debiasing effect caused by voltage drops as current flows through the finger gate terminals.

In addition, common source inductance is at least partially cancelled since the direction of current flow in the gate and source terminals is still in the opposite direction. For example, when the transistor 100 is transitioning on, current flows in the positive y-direction through the finger gate terminal portion 111A. At the same time, since the transistor is turning on, current flows in the negative y-direction through the finger source portion 113A. Thus, common source inductance that might otherwise have been produced due to current flows along the y-axis are at least partially cancelled out for the active region 110A.

Reciprocally, when the transistor 100 is transitioning on, current flows in the negative y-direction through the finger gate terminal portion 111B. At the same time, since the transistor is turning on, current flows in the positive y-direction through the finger source portion 113B. Thus, common source inductance that might otherwise have been produced due to current flows along the y-axis are at least partially cancelled out for the active region 110B. Similar opposing currents happen in the gate and source terminals when the transistor is turning off. Furthermore, because the source bus overlies the gate bus, the effective inductance of the gate loop is reduced due to opposite current direction in the gate and source buses, which improves the switching performance of the transistor.

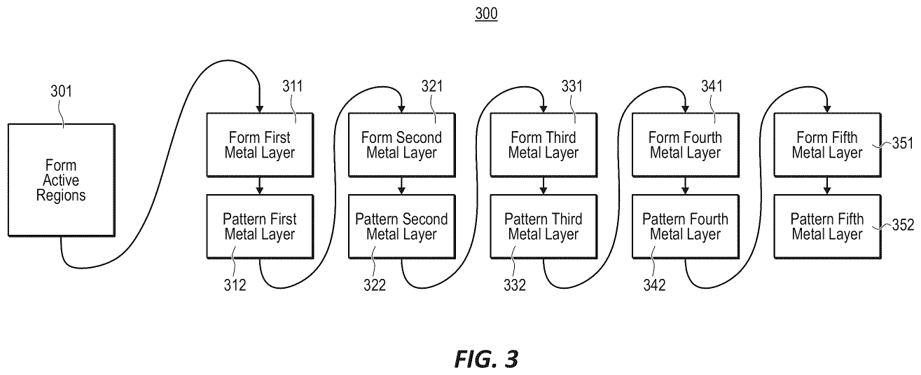

FIG. 3 illustrates a flowchart of a method 300 for fabricating the transistor 100 of FIG. 1. The method 300 will be described with respect to FIGS. 4A through 4F, which illustrate various stages of fabrication. The fabrication will be described with respect to metal layers, and the description of the fabrication steps involved with formation of non-conductive structural portions providing support for the metal layers will be omitted as the principles described herein are not limited to the mechanisms used to form such non-conductive supporting layers.

The fabrication method 300 includes forming a first semiconductor active region and a second semiconductor active region (act 301). FIG. 4A illustrates a top view of a fabrication state 400A in which the active regions 110A and 110B are formed. In an example, the active regions 110A and 110B form what will be the conductive portion of a HEMT, in which two wide bandgap semiconductor layers are layered such that they form a Two-Dimensional Electron Gas (2DEG) therebetween. The 2DEG has high mobility of electrons thereby permitting higher power densities to be transferred.

The fabrication method 300 then includes epitaxially depositing a first metal layer higher than the semiconductor active region in the epitaxial stack (act 311). For example, the gate metal layer 211 of FIG. 2 may be deposited. The first metal layer is then patterned to form the finger gate terminal (act 312). For instance, FIG. 4B illustrates a fabrication state 400B of the transistor 100 of FIG. 1 in which the gate terminal 111 is deposited over the active regions 110A and 110B.

After this, the fabrication method 300 includes epitaxially depositing a second metal layer higher than the first metal layer in the epitaxial stack (act 321). For example, the shield metal layer 212 of FIG. 2 may be deposited. The second metal layer is then patterned to form the shield metal (act 322). For instance, FIG. 4C illustrates a fabrication state 400C of the transistor 100 of FIG. 1 which builds upon the fabrication state 400B of FIG. 4B by adding the shield metal 112 over the gate terminal 111.

Thereafter, the fabrication method 300 includes epitaxially depositing a third metal layer higher than the second metal layer in the epitaxial stack (act 331). For example, the source and drain metal layer 213 of FIG. 2 may be deposited. The third metal layer is then patterned to form the finger source terminal and finger drain terminal (act 332). For instance, FIG. 4D illustrates a fabrication state 400D of the transistor 100 FIG. 1 which builds upon the fabrication state 400C of FIG. 4C by adding the source finger terminal 113 and the drain finger terminal 116.

Thereafter, the fabrication method 300 includes epitaxially depositing a fourth metal layer higher than the third metal layer in the epitaxial stack (act 341). For example, the fourth metal layer may be the metal layer 214 of FIG. 2. The fourth metal layer is then patterned to form vias to connect the finger source terminal and the finger drain terminal to respective buses (act 342). For instance, FIG. 4E illustrates a fabrication state 400E of the transistor 100 of FIG. 1 which builds upon the fabrication state 400D of FIG. 4D by adding the source finger terminal 113 and the drain finger terminal 116.

Thereafter, the fabrication method 300 includes epitaxially depositing a fifth metal layer higher than the fourth metal layer in the epitaxial stack (act 351). For example, the fifth metal layer may be the bus metal layer 215 of FIG. 2. The fifth metal layer is then patterned to form the source bus and the drain bus (act 352). For instance, FIG. 4F illustrates a fabrication state 400F of the transistor 100 of FIG. 1 which builds upon the fabrication state 400E of FIG. 4E by adding the source bus 115 and the drain bus 117. In fabrication state 400F, the fabrication has reached the state also illustrated in FIG. 1.

FIG. 1 illustrates an example embodiment of a lateral field effect transistor 100 in which the gate bus 111C and the source bus 115 are positioned at the mid-point of the y-extent of the transistor 100, where the y-extent of the transistor means the extent along the y-axis of all active regions for that finger in the transistor 100. This, in FIG. 1, the y-extent of the transistor 100 is from the top (the greatest y position) of the active region 110A to the bottom (the least y position) of the active region 110B. This is advantageous as it approximately equals out the mitigation of debiasing along each side of the gate bus. However, the principles described herein are not limited to the gate bus and source bus being exactly at the mid-point of the y-axis extent of the fingers. Some lesser (but still helpful) level of debiasing may be achieved if the gate bus is positioned between 40 and 60 percent along the y-axis extent of the finger (e.g., within 10 percent of the mid-point of the y-axis extent of the finger). Some debiasing may be achieved even if the gate bus is positioned between 25 and 75 percent along the y-axis extent of the finger.

Furthermore, although FIG. 1 illustrates only one gate bus positioned at an intermediate y-axis position of the fingers, there may be multiple gate buses and corresponding source busses positioned at various intermediate positions of the fingers. While this increases the complexity in patterning the gate terminal and the vias, debiasing may be even further mitigated as this even further reduces the distance along the finger gate terminal and source finger gate terminal that the current travels, and thus further preserves gate-to-source voltage.

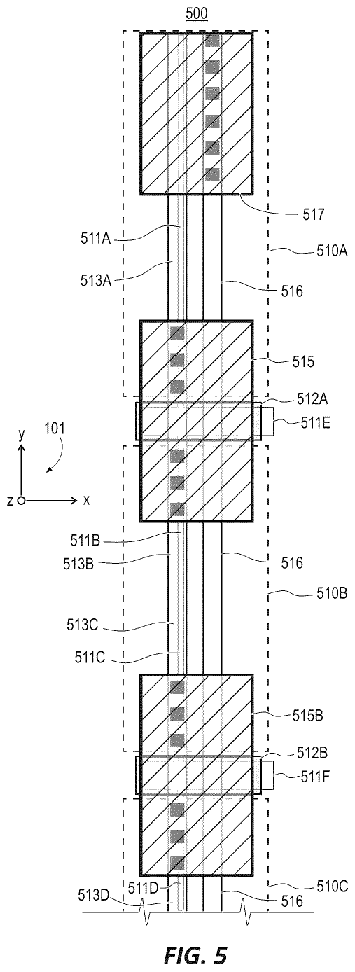

FIG. 5 illustrates a top view of such an example lateral field effect transistor 500. Here there may be even more active regions with a corresponding gate bus formed between each. For instance, a first gate bus 511E and a first source bus 515A is formed between the active region 510A and the active region 510B. Furthermore, a second gate bus 511F and a second source bus 515B is formed between the active region 510B and the act region 510C. This may continue for any number of active regions positioned at different points along the y-axis and any number of corresponding gate and source buses positioned between such active regions.

In the transistor 500, the first gate bus 511E has a positive finger 511A elongated in the positive y-direction, and a negative finger 511B elongated in the negative y-direction. Similarly, the first source bus 515A connects to a proximate end of a positive finger 513A elongated in the positive y-direction, and a negative finger 513B elongated in the negative y-direction. The positive finger gate terminal portion 511A extends parallel to and along the positive finger source portion 513A, and the negative finger gate terminal portion 511B extends parallel to and along the negative source portion 512B.

Moving to the interface between the active regions 510B and 510C, the second gate bus 511F has a positive finger 511C elongated in the positive y-direction, and a negative finger 511D elongated in the negative y-direction. Similarly, the second source bus 515B connects to a proximate end of a positive finger 513C elongated in the positive y-direction, and a negative finger 513D elongated in the negative y-direction. The positive finger gate terminal portion 511C extends parallel to and along the positive finger source portion 513C and actually merges with the negative finger gate terminal portion 511B of the first gate bus 511E. The negative finger gate terminal portion 511D extends parallel to and along the negative source portion 512D.

The gate busses are all electrically connected, and each finger gate terminal portion is collinear and electrically connected by the gate busses. The finger source portions are also likewise co-linear and connect to the respective source bus at the proximate end of the respective finger source portion. The finger source portions may also be contiguous so as to define a single elongated finger source terminal. The structure may continue for any number of gate buses along the y-extent of the finger of the transistor.

### Literal Support Section

Clause 1. A lateral field effect transistor comprising: a source bus; a gate bus; a finger drain terminal elongated in a lateral plane that is parallel to an epitaxial plane of an epitaxial stack; a finger source terminal that is elongated parallel to the finger drain terminal in the lateral plane; and a finger gate terminal that is also elongated parallel to the finger drain terminal and the finger source terminal in the lateral plane, the finger source terminal comprising: a first finger source portion connected to the source bus at a proximate end of the first finger source portion that is proximate the gate bus, and that is elongated away from the gate bus in a first direction; and a second finger source portion that is connected to the source bus at a proximate end of the second finger source portion that is proximate the gate bus, and that is elongated away from the gate bus in a second direction that is opposite the first direction; and the finger gate terminal comprising: a first finger gate terminal portion that extends along the first finger source portion, the first finger gate terminal portion being connected to the gate bus at a proximate end of the first finger gate terminal portion and elongated away from the gate bus in the first direction; and a second finger gate terminal portion that extends along the second finger source portion, the second finger gate terminal portion being connected to the gate bus at a proximate end of the second finger gate terminal portion and elongated away from the gate bus in the second direction opposite the first direction.
Clause 2. The lateral field effect transistor of Clause 1, the finger gate terminal being closer to the finger source terminal than the finger drain terminal.
Clause 3. The lateral field effect transistor of Clause 1, the gate bus extending across an intersecting portion of the finger drain terminal.
Clause 4. The lateral field effect transistor of Clause 3, further comprising a shield layer disposed between the gate bus and the intersecting portion of the finger drain terminal in a direction perpendicular to the epitaxial plane.
Clause 5. The lateral field effect transistor of Clause 1, further comprising: a drain bus connected at one end of the finger drain terminal.
Clause 6. The lateral field effect transistor of Clause 5, the finger gate terminal and the gate bus formed of a first metal layer, the finger drain terminal and the finger source terminal formed of a second metal layer, and the source bus and the drain bus formed a third metal layer.
Clause 7. The lateral field effect transistor of Claim 1, the lateral field effect transistor being a High Electron Mobility Transistor (HEMT).
Clause 8. The lateral field effect transistor of Clause 7, the HEMT being a Gallium Nitride (GaN) HEMT.
Clause 9. The lateral field effect transistor of Clause 8, the source bus overlying the gate bus.
Clause 10. The lateral field effect transistor of Clause 8, the first metal layer, the second metal layer, and the third metal layer formed in that order in the epitaxial stack.
Clause 11. The lateral field effect transistor of Clause 1, the first finger source portion and the second finger source portion being colinear.
Clause 12. The lateral field effect transistor of Clause 11, the finger source terminal being a single finger such that the first finger source portion and the second finger source portion are contiguous.
Clause 13. The lateral field effect transistor of Clause 12, the first finger gate terminal portion and the second finger gate terminal portion being colinear.
Clause 14. The lateral field effect transistor of Clause 1, the gate bus being a first gate bus, the lateral field effect transistor further comprising: a second source bus; and a second gate bus, the finger source terminal further comprising: a third finger source portion connected to the second source bus at a proximate end of the third finger source portion that is proximate the second gate bus, and that is elongated away from the second gate bus in the first direction; and a fourth finger source portion that connected to the second source bus at a proximate end of the fourth finger source portion that is proximate the second gate bus, and that is elongated away from the second gate bus in the second direction; and the finger gate terminal further comprising: a third finger gate terminal portion that extends along the third finger source portion, the third finger gate terminal portion being connected to the second gate bus at a proximate end of the third finger gate terminal portion and elongated away from the second gate bus in the first direction; and a fourth finger gate terminal portion that extends along the fourth finger source portion, the fourth finger gate terminal portion being connected to the second gate bus at a proximate end of the fourth finger gate terminal portion and elongated away from the second gate bus in the second direction.
Clause 15. The lateral field effect transistor of Clause 14, the first gate bus and the second gate bus being electrically connected.
Clause 16. The lateral field effect transistor of Clause 14, the finger source terminal being a single finger such that the first finger source portion, the second finger source portion, the third finger source portion, and the fourth finger source portion are contiguous.
Clause 17. The lateral field effect transistor of Clause 14, the finger drain terminal being a single finger.
Clause 18. The lateral field effect transistor of Clause 14, the finger gate terminal being a single finger such that the first finger gate terminal portion, the second finger gate terminal portion, the third finger gate terminal portion, and the fourth finger gate terminal portion are collinear.
Clause 19. The lateral field effect transistor of Clause 18, the first finger gate terminal portion, the second finger gate terminal portion, the third finger gate terminal portion, and the fourth finger gate terminal portion also being contiguous.
Clause 20. A fabrication method for fabricating a lateral field effect transistor through formation of an epitaxial stack, the fabrication method comprising: forming a first semiconductor active region and a second semiconductor active region; epitaxially depositing a first metal layer higher than the first semiconductor active region and the second semiconductor active region in the epitaxial stack; patterning the first metal layer to form a finger gate terminal that comprises a gate bus, a first finger gate terminal portion that extends from the gate bus parallel to an epitaxial plane of the epitaxial stack over the first semiconductor active region in a first direction, and a second finger gate terminal portion that extends from the gate bus parallel to an epitaxial plane of the epitaxial stack over the second semiconductor active region in a second direction that is opposite the first direction; epitaxially depositing a second metal layer higher than the first metal layer in the epitaxial stack; patterning the second metal layer to form a finger drain terminal and a finger source terminal, the finger source terminal comprising a first finger source portion that extends in the first direction along the first finger gate terminal portion, and a second finger source portion that extends in the second direction along the second finger gate terminal portion; the finger drain terminal comprising: a first finger drain portion that extends in the first direction along the first finger gate terminal portion, and a second finger drain portion that extends in the second direction along the second finger gate terminal portion; epitaxially depositing a third metal layer higher than the second metal layer in the epitaxial stack; and patterning the third metal layer to form a source bus and a drain bus, the source bus overlying a proximate end of the first finger source portion and a proximate end of the second finger source portion, the drain bus overlying a proximate end of the first finger drain portion and a proximate end of the second finger drain portion, wherein the fabrication method further includes the formation of vias that extend through a portion of the epitaxial stack such that the source bus is electrically connected to the proximate end of the first finger source portion and the proximate end of the second finger source portion, the drain bus is electrically connected to an end of the finger drain terminal.

Although the subject matter has been described in language specific to structural features and/or methodological acts, it is to be understood that the subject matter defined in the appended claims is not necessarily limited to the described features or acts described above, or the order of the acts described above. Rather, the described features and acts are disclosed as example forms of implementing the claims.

The present disclosure may be embodied in other specific forms without departing from its essential characteristics. The described embodiments are to be considered in all respects only as illustrative and not restrictive. All changes which come within the meaning and range of equivalency of the claims are to be embraced within their scope.

When introducing elements in the appended claims, the articles “a,” “an,” “the,” and “said” are intended to mean there are one or more of the elements. The terms “comprising,” “including,” and “having” are intended to be inclusive and mean that there may be additional elements other than the listed elements.

What is claimed is:

1. A lateral field effect transistor comprising:
a source bus;
a gate bus;
a finger drain terminal elongated in a lateral plane that is parallel to an epitaxial plane of an epitaxial stack;
a finger source terminal that is elongated parallel to the finger drain terminal in the lateral plane; and
a finger gate terminal that is also elongated parallel to the finger drain terminal and the finger source terminal in the lateral plane,
the finger source terminal comprising:
a first finger source portion connected to the source bus at a proximate end of the first finger source portion that is proximate the gate bus, and that is elongated away from the gate bus in a first direction; and
a second finger source portion that is connected to the source bus at a proximate end of the second finger source portion that is proximate the gate bus, and that is elongated away from the gate bus in a second direction that is opposite the first direction; and
the finger gate terminal comprising:
a first finger gate terminal portion that extends along the first finger source portion, the first finger gate terminal portion being connected to the gate bus at a proximate end of the first finger gate terminal portion and elongated away from the gate bus in the first direction; and
a second finger gate terminal portion that extends along the second finger source portion, the second finger gate terminal portion being connected to the gate bus at a proximate end of the second finger gate terminal portion and elongated away from the gate bus in the second direction opposite the first direction.

2. The lateral field effect transistor of claim 1, the finger gate terminal being closer to the finger source terminal than the finger drain terminal.

3. The lateral field effect transistor of claim 1, the gate bus extending across an intersecting portion of the finger drain terminal.

4. The lateral field effect transistor of claim 3, further comprising a shield layer disposed between the gate bus and the intersecting portion of the finger drain terminal in a direction perpendicular to the epitaxial plane.

5. The lateral field effect transistor of claim 1, further comprising:
a drain bus connected at one or approximately one end of the finger drain terminal.

6. The lateral field effect transistor of claim 5, the finger gate terminal and the gate bus formed of a first metal layer, the finger drain terminal and the finger source terminal formed of a second metal layer, and the source bus and the drain bus formed a third metal layer.

7. The lateral field effect transistor of claim 1, the lateral field effect transistor being a High Electron Mobility Transistor (HEMT).

8. The lateral field effect transistor of claim 7, the HEMT being a Gallium Nitride (GaN) HEMT.

9. The lateral field effect transistor of claim 8, the source bus overlying the gate bus.

10. The lateral field effect transistor of claim 8, the first metal layer, the second metal layer, and the third metal layer formed in that order in the epitaxial stack.

11. The lateral field effect transistor of claim 1, the first finger source portion and the second finger source portion being colinear.

12. The lateral field effect transistor of claim 11, the finger source terminal being a single finger such that the first finger source portion and the second finger source portion are contiguous.

13. The lateral field effect transistor of claim 12, the first finger gate terminal portion and the second finger gate terminal portion being colinear.

14. The lateral field effect transistor of claim 1, the gate bus being a first gate bus, the lateral field effect transistor further comprising:
a second source bus; and
a second gate bus,
the finger source terminal further comprising:
a third finger source portion connected to the second source bus at a proximate end of the third finger source portion that is proximate the second gate bus, and that is elongated away from the second gate bus in the first direction; and
a fourth finger source portion that connected to the second source bus at a proximate end of the fourth finger source portion that is proximate the second gate bus, and that is elongated away from the second gate bus in the second direction; and
the finger gate terminal further comprising:
a third finger gate terminal portion that extends along the third finger source portion, the third finger gate terminal portion being connected to the second gate bus at a proximate end of the third finger gate terminal portion and elongated away from the second gate bus in the first direction; and
a fourth finger gate terminal portion that extends along the fourth finger source portion, the fourth finger gate terminal portion being connected to the second gate bus at a proximate end of the fourth finger gate terminal portion and elongated away from the second gate bus in the second direction.

15. The lateral field effect transistor of claim 14, the first gate bus and the second gate bus being electrically connected.

16. The lateral field effect transistor of claim 14, the finger source terminal being a single finger such that the first finger source portion, the second finger source portion, the third finger source portion, and the fourth finger source portion are contiguous.

17. The lateral field effect transistor of claim 14, the finger drain terminal being a single finger.

18. The lateral field effect transistor of claim 14, the finger gate terminal being a single finger such that the first finger gate terminal portion, the second finger gate terminal portion, the third finger gate terminal portion, and the fourth finger gate terminal portion are collinear.

19. The lateral field effect transistor of claim 18, the first finger gate terminal portion, the second finger gate terminal portion, the third finger gate terminal portion, and the fourth finger gate terminal portion also being contiguous.

20. A fabrication method for fabricating a lateral field effect transistor through formation of an epitaxial stack, the fabrication method comprising:
forming a first semiconductor active region and a second semiconductor active region;
epitaxially depositing a first metal layer higher than the first semiconductor active region and the second semiconductor active region in the epitaxial stack;
patterning the first metal layer to form a finger gate terminal that comprises a gate bus, a first finger gate terminal portion that extends from the gate bus parallel to an epitaxial plane of the epitaxial stack over the first semiconductor active region in a first direction, and a second finger gate terminal portion that extends from the gate bus parallel to an epitaxial plane of the epitaxial stack over the second semiconductor active region in a second direction that is opposite the first direction;
epitaxially depositing a second metal layer higher than the first metal layer in the epitaxial stack;
patterning the second metal layer to form a finger drain terminal and a finger source terminal, the finger source terminal comprising a first finger source portion that extends in the first direction along the first finger gate terminal portion, and a second finger source portion that extends in the second direction along the second finger gate terminal portion; the finger drain terminal comprising: a first finger drain portion that extends in the first direction along the first finger gate terminal portion, and a second finger drain portion that extends in the second direction along the second finger gate terminal portion;
epitaxially depositing a third metal layer higher than the second metal layer in the epitaxial stack; and
patterning the third metal layer to form a source bus and a drain bus, the source bus overlying a proximate end of the first finger source portion and a proximate end of the second finger source portion, the drain bus overlying a proximate end of the first finger drain portion and a proximate end of the second finger drain portion,
wherein the fabrication method further includes the formation of vias that extend through a portion of the epitaxial stack such that the source bus is electrically connected to the proximate end of the first finger source portion and the proximate end of the second finger source portion, the drain bus is electrically connected to an end of the finger drain terminal.
